(19) United States
(12) Patent Application Publication
(10) Pub. No.: US 2026/0050031 A1
(43) Pub. Date: Feb. 19, 2026

(54) DEVICE INTERFACE AND METHOD OF TESTING USING THE SAME

(71) Applicant: ADVANTEST CORPORATION, Tokyo (JP)

(72) Inventors: Haokun Zhang, Tokyo (JP); Gang Zhao, Tokyo (JP)

(21) Appl. No.: 19/248,305

(22) Filed: Jun. 24, 2025

(30) Foreign Application Priority Data
Aug. 19, 2024 (CN) 202411137412.X

(51) Int. Cl. G01R 31/28; G01R 1/04

(52) U.S. Cl. CPC G01R 31/2889; G01R 1/0441

(57) ABSTRACT

A device interface disposed between a test head and a device under test is disclosed. The device interface includes a first mounting structure, a second mounting structure, and an interconnection structure. The interconnection structure includes a first probe device, a second probe device, and a connecting component which is electrically connected to the first probe device and the second probe device. The first probe device is slidably mounted on the first mounting structure and adapted to be electrically connected to a performance board of the device under test. The second prob is slidably mounted on the second mounting structure and adapted to be electrically connected to a probe module of the test head. The device interface increases a usable area on the performance board of the device under test and improves a flexibility of the performance board usage. A method of testing utilizing the device interface is also provided.

### FIELD OF THE INVENTION

The present invention relates to a test device for semiconductor devices, and more particularly to a device interface disposed between a test head and a device under test, and a method of testing using the same.

### BACKGROUND OF THE INVENTION

Typically, a test device for semiconductor devices includes a test head, and a performance board or a loadboard on the test head. Devices under test are carried on the performance board and therefore signals output from the test head are transmitted to the devices under test.

The test head includes a test resource circuit board and probe modules. The probe modules typically include probe sockets and a plurality of vertical-type probes inserted in the probe sockets. The probe modules are electrically connected to the test resource circuit board and electrically connected to the devices under test by using the vertical-type probes to contact the performance board directly. However, due to the circuit layout on the circuit board, empty areas typically exist among the plurality of probe modules arranged on the circuit board or a spacing between the two adjacent probe modules might be large. Thus, a larger test resource area is required to be reserved on the performance board which is connected to the vertical-type probes of the probe modules, leading to an insufficient usable area for the device placement on the performance board.

### SUMMARY OF THE INVENTION

The present invention provides a device interface and a method of testing using the same so as to increase the usable areas on the performance board and improve a flexibility of the performance board usage.

To achieve one, some, or all of the aforementioned purposes or other purposes, an embodiment of the present invention provides a device interface disposed between a test head and a device under test. The test head includes a probe module. The device under test includes a performance board. The device interface includes a first mounting structure, a second mounting structure, and an interconnection structure. The interconnection structure includes a first probe device and a second probe device, and a connecting component which is electrically connected to the first probe device and the second probe device. The first probe device is slidably mounted on the first mounting structure and adapted to be electrically connected to the performance board. The second probe device is slidably mounted on the second mounting structure and adapted to be electrically connected to the probe module.

In an embodiment of the present invention, in the interconnection structure, a quantity of the at least one first probe device is one, and a quantity of the at least one second probe device is one. The connecting component is electrically connected to the first probe device and the second probe device.

In an embodiment of the present invention, a quantity of the at least one first probe device is one, and a quantity of the at least one second probe device is plural. The plurality of the second probe devices are electrically connected to the same first probe device through the connecting component.

In an embodiment of the present invention, a quantity of the at least one first probe device is plural, and a quantity of the at least one second probe device is one. The plurality of the first probe devices are electrically connected to the same second probe device through the connecting component.

In an embodiment of the present invention, the connecting component is a cable.

In an embodiment of the present invention, the connecting component is a flexure print circuit board.

In an embodiment of the present invention, the interconnection structure further includes a signal quality enhancement module which is disposed on and electrically connected to the flexure print circuit board In an embodiment of the present invention, the device interface further includes a base. The base includes a first loading side and a second loading side opposite the first loading side. The first loading side includes a first probe configuration area, and the second loading side includes a second probe configuration area. The first mounting structure is disposed in the first probe configuration area, and the second mounting structure is disposed in the second probe configuration area. The connecting component is disposed within the base.

In an embodiment of the present invention, the first probe configuration area includes two divided and opposite rectangular areas, or two divided and opposite semi-ring areas or a frame-shaped area.

In an embodiment of the present invention, a size of the first probe configuration area is less than or equal to that of the second probe configuration area.

In an embodiment of the present invention, a quantity of the at least one interconnection structure is plural. The device interface further includes an adjusting structure disposed in the base to separate the connecting components of the interconnection structures.

In an embodiment of the present invention, the first mounting structure includes a first frame and a plurality of first rail structures. The first frame is disposed in the first probe configuration area in the first loading side of the base. The first frame includes two divided first side frames and a plurality of first support members which are disposed at intervals and connected to both of the first side frames for forming a plurality of first adjusting areas. The first rail structures are disposed on the first support member and on two opposite sides of each of the first adjusting areas.

In an embodiment of the present invention, each of the first probe devices includes a first probe socket and a plurality of first pogo pins. The first probe socket includes two opposite first guiding bumps adapted for being movably assembled on the first rail structure to enable the first probe socket to slide in the first adjusting area along a first direction. A portion of the first probe socket extends between the first frame and the performance board. The first pogo pins are assembled on the first probe socket and protrudes from the first probe socket. One end of the first pogo pins is connected to the connecting component while the other end of the first pogo pins is configured to be electrically connected to the performance board.

In an embodiment of the present invention, the first mounting structure further includes a fixing rib structure and a plurality of adjusting rib structures. The fixing rib structure includes a fixing part and a plurality of suspended ribs. The fixing part is disposed on one of the two first side frames. The suspended ribs are arranged at intervals on the fixing part. The suspended ribs are arranged corresponding to the first support members. The suspended ribs and the corresponding first support members form a slidable space. The adjusting rib structures are arranged corresponding to the first adjustable areas. Each of the adjusting rib structures includes a limiting part and two sliding ribs. The two sliding ribs are slidably arranged on the first support members on the two sides of the first adjustable area and configured to slide in the slidable space for moving the limiting part close to or away from the fixing part of the fixing rib structures. The limiting part is configured to support an inner surface of the performance board facing the first probe device.

In an embodiment of the present invention, the second mounting structure includes a second frame and a plurality of second rail structures. The second frame is disposed in the second probe configuration area on the second loading side of the base. The second frame includes two divided second side frames and a plurality of second support members. The second support members are disposed at intervals and connected to the two second side frames for forming a plurality of second adjusting areas corresponding to the first adjusting areas respectively. The second rail structures are disposed on the second support member and on two opposite sides of each of the second adjusting areas. The second rail structures correspond to the first rail structures respectively.

In an embodiment of the present invention, the second probe device includes a second pin socket and a second pogo pin. Two opposite sides of the second probe socket are adapted for being movably assembled on the second rail structure to make the second probe socket slide in the second adjusting area along a first direction. The second pogo pins are assembled on the second probe socket and protrudes from the second probe socket. One end of the second pogo pins is connected to the connecting component while the other end of the second pogo pins is adapted to be electrically connected to the probe module.

In an embodiment of the present invention, the device interface further includes a device interface board and a docking frame. The docking frame is adapted to be assembled onto the test head. The device interface board is disposed between the second frame and the docking frame. The second pogo pins are electrically connected to the probe module through a transition structure formed by the device interface board.

In an embodiment of the present invention, the second pogo pin includes a receptacle at one end toward the test head adapted to receive a test resource probe of the probe module and form an electrical connection therebetween

According to an embodiment of the present invention, a method of testing using the aforementioned device interface is also disclosed. The method includes sliding the second probe device to a position corresponding to the probe module of the test head wherein the second probe device is electrically connected to the probe module. Next, the first probe device is slid to a position corresponding to a test resource area of the performance board. An adjusting rib structure is slid to limit a position of the first probe device. After that, the performance board is mounted onto the first probe device. The first probe device is electrically connected to the test resource area, and the adjusting rib structure supports an inner surface of the performance board facing the first probe device.

In an embodiment of the present invention, the movement of the first probe device, the second probe device, and the adjusting rib structure can be automatically controlled through programing.

In the present invention, an interconnection structure including a first probe device, a second probe device, and a connecting component is provided. In addition, the first probe device and the second probe device can be slid on the first direction. Thus, a performance board with a fixed test resource area distribution can be applied to various types of test heads, leading to improving a flexibility of applications of the test head and the performance board. Furthermore, it also solves the problem in traditional test devices caused by the unreasonable configuration of probe modules in the standard test heads, which results in the test resource area on the performance board occupying a large space, thereby leading to an insufficient space for the electronic component placement.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of an arrangement of a device interface, a test head, and a device under test according to an embodiment of the present invention.

FIG. 2 is a schematic perspective view of a device interface and a performance board according to an embodiment of the present invention.

FIG. 3 is a schematic exploded view of a device interface according to an embodiment of the present invention.

FIG. 4 is a schematic diagram of an assembly of the performance board and a device interface according to an embodiment of the present invention.

FIG. 5 is a local amplified diagram of the device interface of FIG. 2.

FIG. 6 is a schematic diagram of an interconnection structure according to a first embodiment of the present invention.

FIG. 7 is a schematic diagram of an application of a device interface according to an embodiment of the present invention.

FIG. 8 is a schematic top view of an application of a device interface and a performance board according to an embodiment of the present invention.

FIG. 9 is a schematic diagram of an interconnection structure according to a second embodiment of the present invention.

FIG. 10 is a schematic perspective view of a device interface and a performance board according to another embodiment of the present invention.

FIG. 11 is a schematic diagram of an interconnection structure according to a third embodiment of the present invention.

FIG. 12 is a schematic diagram of an interconnection structure according to a fourth embodiment of the present invention.

FIG. 13 is a schematic diagram of an interconnection structure according to a fifth embodiment of the present invention.

FIG. 14 is a schematic flow chart of a method of testing using the device interface according to an embodiment of the present invention.

### DETAILED DESCRIPTION OF PREFERRED EMBODIMENTS

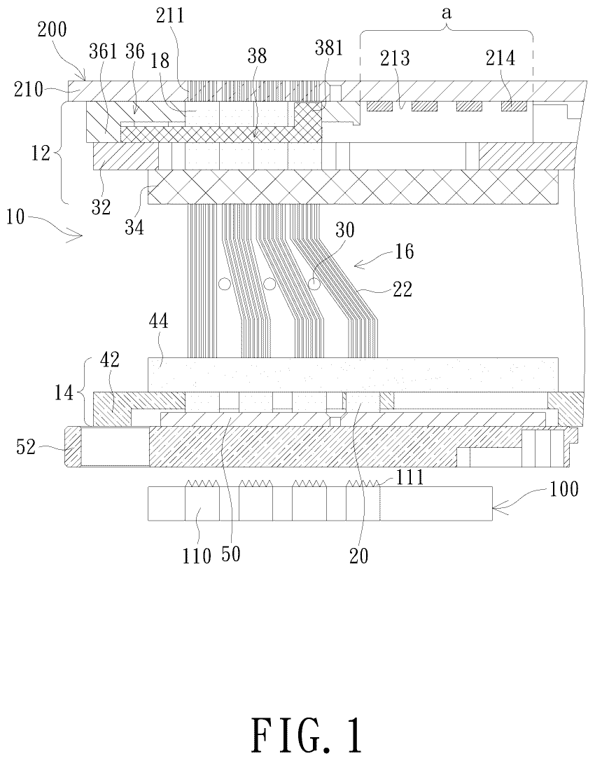

FIG. 1 is a schematic diagram showing an arrangement of a device interface, a test head, and a device under test according to an embodiment of the present invention. As shown in FIG. 1, a test head 100 includes a probe module 110. A device under test 200 includes a performance board 210 or a loadboard. A device interface 10 is disposed between the probe module 110 and the performance board 210. The device interface 10 includes a first mounting structure 12, a second mounting structure 14, and an interconnection structure 16. The first mounting structure 12 and the second mounting structure 14 are described in detail in the following. The interconnection structure 16 includes a first probe device 18, a second probe device 20, and a connecting component 22. The connecting component 22 is electrically connected to the first probe device 18 and the second probe device 20. In addition, the first probe device 18 is slidably mounted on the first mounting structure 12 and adapted to be electrically connected to the performance board 210. The second probe device 20 is slidably mounted on the second mounting structure 14 and adapted to be electrically connected to the probe module 110.

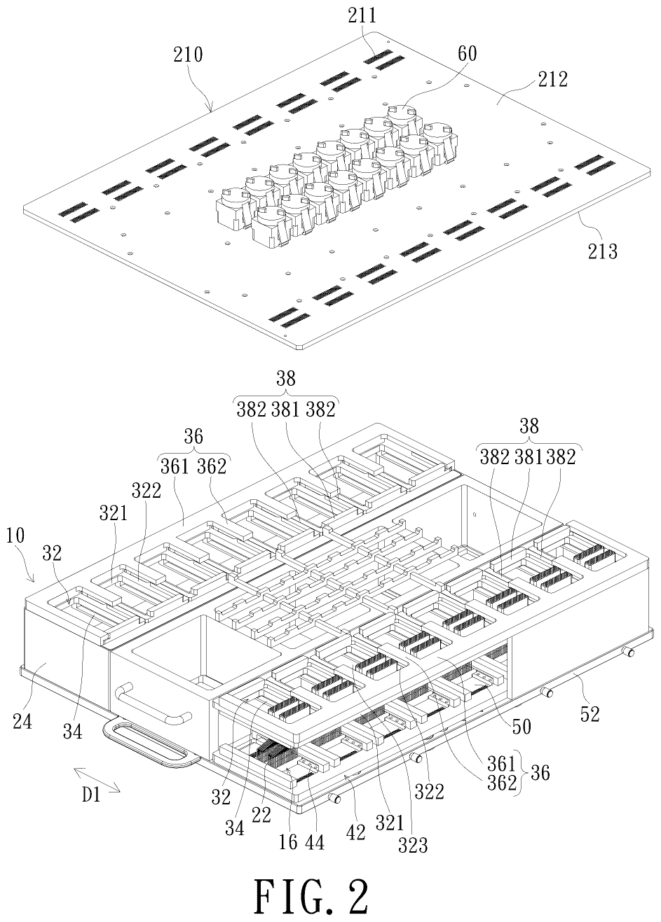

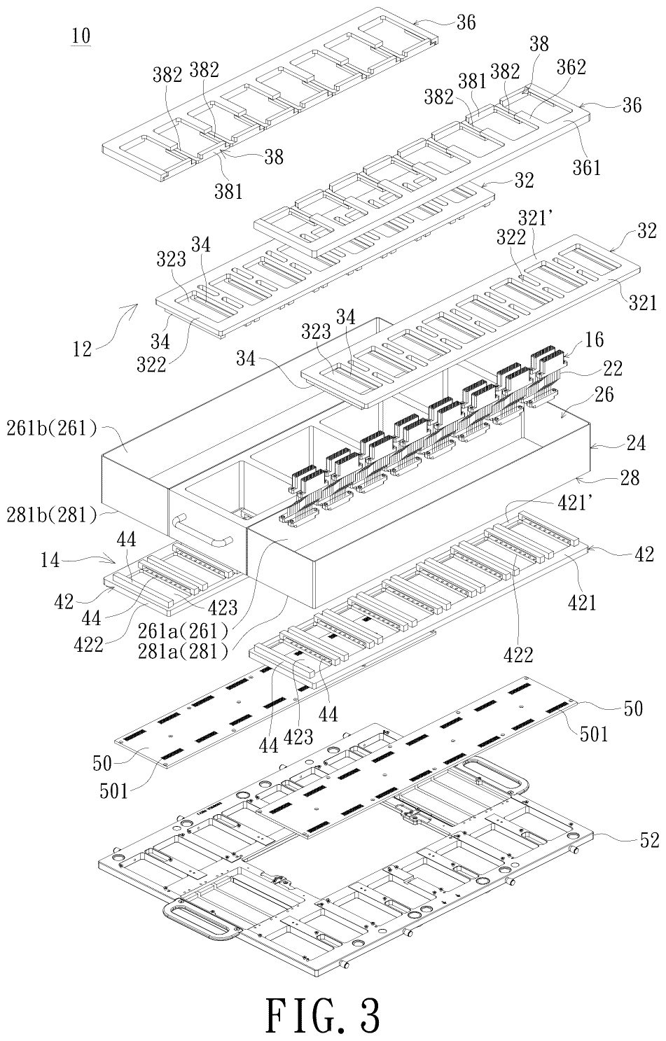

FIG. 2 is a schematic perspective view of a device interface and a performance board according to an embodiment of the present invention. FIG. 3 is a schematic exploded view of a device interface according to an embodiment of the present invention. As shown in FIG. 2 and FIG. 3, the device interface 10 further includes a base 24 having a first loading side 26 and a second loading side 28 opposite the first loading side 26. A first probe configuration area 261 is disposed in the first loading side 26 and a second probe configuration area 281 is disposed in the second loading side 28. The first mounting structure 12 is disposed in the first probe configuration area 261 and the second mounting structure 14 is disposed in the second probe configuration area 281. The connecting component 22 of the interconnection structure 16 is disposed in the base 12. Please refer to FIG. 1 to FIG. 3. A quantity of the interconnection structure 16 could be multiple. In an embodiment, the device interface 10 further includes an adjusting structure 30 (as illustrated in FIG. 1) disposed within the base 24 (as illustrated in FIG. 2 and FIG. 3) to separate a plurality of connecting components 22 of the interconnection structures 16. The adjusting structure 30 is illustrated as a pillar structure for example and formed of an isolation material.

In an embodiment, as shown in FIG. 2 and FIG. 3, the first probe configuration area 261 includes two divided and opposite rectangular areas 261a and 261b. The second probe configuration area 281 includes two divided and opposite rectangular areas 281a and 281b. However, the invention is not limited thereto. A size of the first probe configuration area 261 is less than or equal to that of the second probe configuration area 281. The invention is not limited thereto. The performance board 210 is also shown in FIG. 2. A test resource area 211 could be predefined on the performance board 210 for electrically connected to the first probe device 18. In an embodiment, the performance board 210 includes an outer surface 212 and an inner surface 213 opposite each other. A device under test 60 is disposed on the outer surface 212 of the performance board 210. There might be additional electronic devices (not shown) disposed outside the test resource area 211 on the inner surface 213 of the performance board 210 while the electronic devices are electrically connected to the test resource area 211.

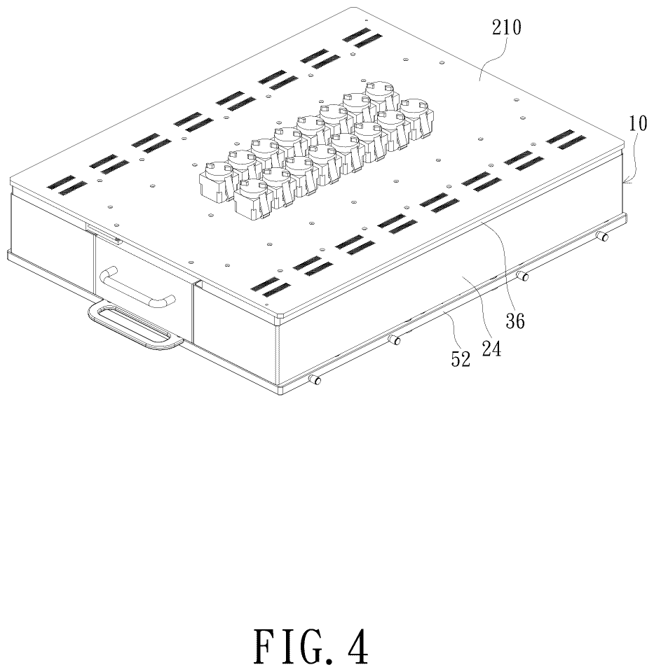

FIG. 4 is a schematic diagram showing an assembly of a performance board and a device interface according to an embodiment of the present invention. As shown in FIG. 2 and FIG. 4, a shape of the performance board 210 corresponds to that of the base 24 but is not limited thereto. The shape of the performance board 210 could not correspond to that of the base 24. In an embodiment which is not illustrated, the base 24 includes various shapes for being compatible with various performance board 210 and/or the test head 100 (as shown in FIG. 1). The first probe configuration area 261 and/or the second probe configuration area 281 could be a shape other than a rectangle, such as two divided and opposite semi-ring areas or a frame-shaped area. Accordingly, the shapes of the first mounting structure 12 and the second mounting structure 14 are changed based on the first probe configuration area 261 and the second probe configuration area 281 respectively. In an embodiment, an interface configuration of the test head 100 might be the same as or different from that of the performance board 210. According to the embodiment of the present invention, by sliding the first probe device 18 and the second probe device 20 and adjusting their positions, the performance board 210 with the same configuration (which means the same distribution of the test resource area 211) can be applied to test head 100 having different configurations. As a result, a flexibility of the test head 100 and the performance board 210 can be further improved.

As shown in FIG. 2 and FIG. 3, the first mounting structure 12 includes a first frame 32 and a plurality of first rail structures 34. The first frame 32 is disposed in the first probe configuration area 261 on the first loading side 26 of the base 24. The second mounting structure 14 includes a second frame 42 and a plurality of second rail structures 44. The second frame 42 is disposed in the second probe configuration area 281 on the second loading side 28 of the base 24. In an embodiment, when each of the first probe configuration area 261 and the second probe configuration area 281 is two divided and opposite rectangular areas 261a/261b and 281a/281b respectively, a quantity of each of the first frame 32 and second frame 34 is two correspondingly. In addition, the first frame 32 and the second frame 42 may have a shape of rectangular but not limited thereto. When each of the first probe configuration area 261 and the second probe configuration area 281 is two divided and opposite semi-ring areas or a frame-shaped area, each of the first frame 32 and the second frame 42 is two divided and opposite semi-ring areas or a frame-shaped area correspondingly. Furthermore, the first frame 32 could have a different shape or profile from the second frame 42.

As shown in FIG. 2 and FIG. 3, each of the first frame 32 located on the first loading side 26 of the base 24 includes two separate first side frames 321 and 321′ and a plurality of first support members 322. The first support members 322 are disposed at intervals and connected to both of the first side frames 321 and 321′ for forming a plurality of first adjusting areas 323. In the embodiment shown in FIG. 2 and FIG. 3, each of the first frame 32 includes eight first adjusting areas 323. The invention is not limited thereto. The first rail structures 34 are disposed on the first support members 322 and located on two opposite sides of each of the first adjusting areas 323. In an embodiment, as shown in FIG. 3, except the first support members 322 adjacent to the two edges of the first side frames 321 and 321′, on which only one set of the first rail structure 34 is disposed, there are two sets of the first rail structures 34 arranged in parallel on each of the other first support members 322 respectively.

In addition, the second frame 42 located on the second loading side 28 of the base 24 includes two separate second side frames 421 and 421′ and a plurality of second support members 422. The second support members 422 are disposed at intervals and connected to both of the second side frames 421 and 421′ for forming a plurality of second adjusting areas 423 corresponding to the plurality of first adjusting areas 323. The second rail structures 44 are disposed on the second support members 422 and located on two opposite sides of each of the second adjusting areas 423. In an embodiment, as shown in FIG. 3, except the second support members 422 adjacent to the two edges of the second side frames 421 and 421′, on which only one set of the second rail structure 44 is disposed, there are two sets of the second rail structures 44 arranged in parallel on each of the other second support members 422 respectively. The plurality of second rail structures 44 are corresponding to the plurality of first rail structures 34 respectively.

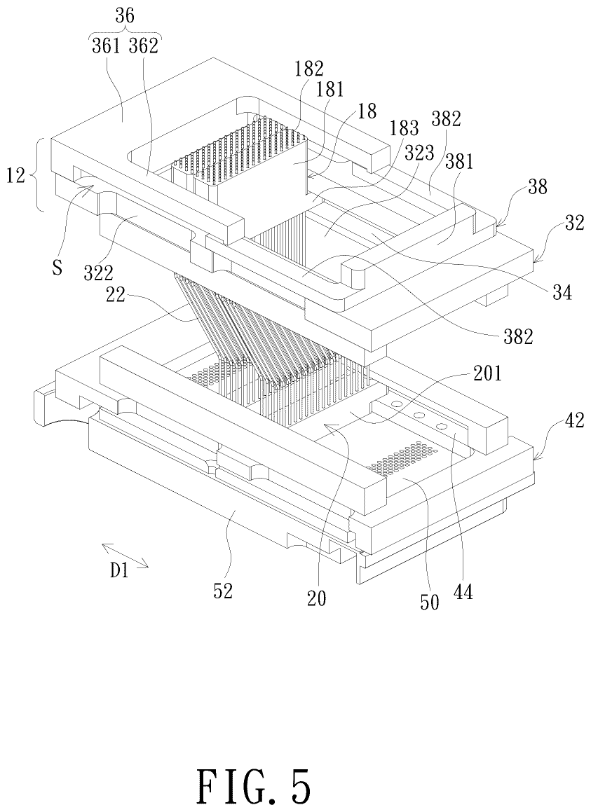

FIG. 5 is a local amplified diagram of the device interface of FIG. 2. As shown in FIG. 1, FIG. 2, FIG. 3, and FIG. 5, in an embodiment, the first mounting structure 12 further includes a fixing rib structure 36 and a plurality of adjusting rib structures 38. A quantity of the fixing rib structure 36 depends on a quantity of the first frame 32, such as two sets of fixing rib structures 36 shown here. Each set of the fixing rib structure 36 includes a fixing part 361 and a suspended rib 362. The fixing part 361 is disposed on the first side frame 321, which is adjacent to the sidewall of the base 24, in the first frame 32. In the embodiment, the suspended ribs 362 are arranged at intervals and connected to the fixing part 361. The suspended ribs 362 are arranged corresponding to the first support members 322. The suspended ribs 362 and the corresponding first support members 322 form a slidable space S as shown in FIG. 5. The adjusting rib structures 38 are arranged corresponding to the first adjusting areas 323. A quantity of the adjusting rib structures 38 is corresponding to the quantity of the first adjusting areas 323. Each of the adjusting rib structures 38 includes a limiting part 381 and two sliding ribs 382. The two sliding ribs 382 are slidably arranged on the first support members 322 on the two sides of the first adjusting area 323 and adapted to slide in the slidable space S for moving the limiting part 381 close to or away from the fixing part 361 of the fixing rib structures 36. Hence, the limiting part 381 is slidable along a first direction D1.

As shown in FIG. 1, the limiting part 381 is adapted to support the inner surface 213 of the performance board 210 facing the first probe device 18. In an embodiment, since the predetermined test resource areas 211 on the performance board 210 are arranged adjacent to each other and located near an edge of the performance board 210 (as shown in FIG. 2), the first probe devices 18 are slid towards the fixing part 361 and arranged adjacent to each other. The first probe devices 18 are electrically connected to the test resource area 211. The adjusting rib structures 38 are also slid toward to the fixing part 361 for limiting the positions of the first probe devices 18. In addition, the limiting parts 381 of the adjusting rib structures 38 support on the inner surface 213 of the performance board 210 adjacent to the edge. A part of a central area between the limiting part 381 and the inner surface 213 can be released to form an additional usable area a, and thereby placing more electronic devices 214 on the performance board 210.

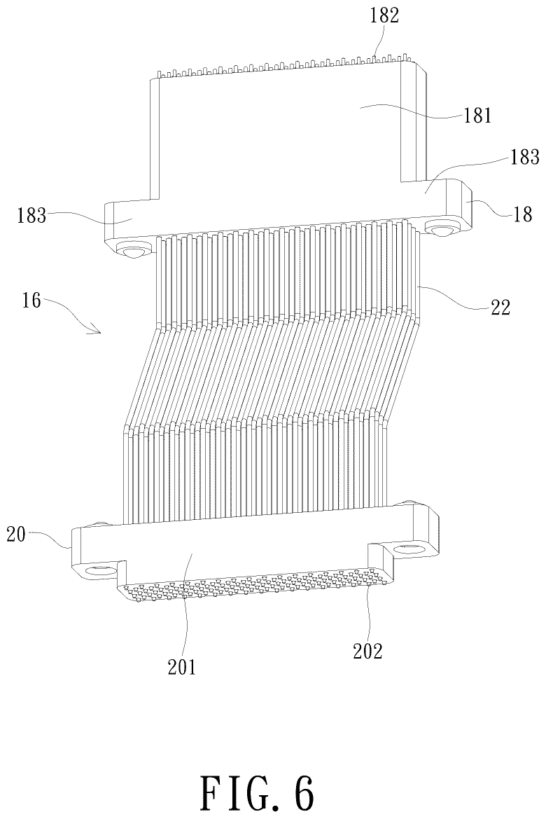

FIG. 6 is a schematic diagram of an interconnection structure according to a first embodiment of the present invention. As shown in FIG. 6, the first probe device 18 of the interconnection structure 16 includes a first probe socket 181 and a plurality of first pogo pins 182. The first pogo pins 182 are assembled on the first probe socket 181 and protrude from the first probe socket 181. The second probe device 20 of the interconnection structure 16 includes a second probe socket 201 and a plurality of second pogo pins 202. The second pogo pins 202 are assembled on the second probe socket 201 and protrude from the second probe socket 201. The connecting component 22 of the interconnection structure 16 is connected to the first pogo pins 182 and the second pogo pins 202. As shown in FIG. 5, the first probe socket 181 includes two opposite first guiding bumps 183 adapted for being movably assembled on the first rail structures 34, enabling the first probe socket 181 to slide in the first adjusting area 323 along a first direction D1. A portion of the first probe socket 181 extends between the first frame 32 and the performance board 210 (as shown in FIG. 1). One end of each of the first pogo pins 182 is connected to the connecting component 22 while the other end of each of the first pogo pins 182, which is away from the connecting component 22, is adapted to be electrically connected to the performance board 210. Correspondingly, two opposite sides of the second probe socket 201 are adapted to movably assembled on the second rail structures 44, enabling the second probe socket 201 sliding along the first direction D1 in the second adjusting area 423 (shown in FIG. 3). One end of each of the second pogo pins 202 is connected to the connecting component 22 while the other end of each of the second pogo pins 202, which is away from the connecting component 22, is adapted to be electrically connected to the probe module 110 (shown in FIG. 1).

In an embodiment, the first probe socket 181 and the second probe socket 201 are strips as shown in FIG. 6 but not limited thereto. In an embodiment not shown here, the first probe socket 181 and the second probe socket 201 can be blocks or circular sectors. In addition, the first probe socket 181 and the second probe socket 201 may have the same or different shapes. In an embodiment, a quantity of the second pogo pins 202 of the second probe device 20 can be the same as or different from a quantity of the first pogo pins 182 of the first probe device 18. For example, the quantity of the second pogo pins 202 can be less than the quantity of the first pogo pins 182 but not limited thereto. In another embodiment, the quantity of the second pogo pins 202 can be greater than the quantity of the first pogo pins 182.

As shown in FIG. 1 to FIG. 5, the device interface 10 further includes a device interface board 50 and a docking frame 52. The docking frame 52 is adapted for assembling on the test head 100 (as shown in FIG. 1). The device interface board 50 may have a quantity and shape corresponding to the quantity and the shape of the second frame 42. The device interface board 50, bearded by the docking frame 52, is disposed between the second frame 42 and the docking frame 52. A transition structure 501 is formed on the device interface board 50. Since the second pogo pins 202 are needle-shaped and exposed from the second probe socket 201 and the probe module 110 (shown in FIG. 1) includes a needle-shaped test resource probe 111, the transition structure 501 can be a receptacle adapted for receiving the second pogo pins 202 and the test resource probe 111 of the probe module 110 and being electrically connected to the second pogo pins 202 and the test resource probe 111. Thus, the second pogo pins 202 and the probe module 110 are electrically connected through the transition structurer 501. It is noted that a distribution of the transition structure 501 illustrated here is a schematic diagram, the positions of the transition structure 501 are corresponding to the layout of the probe module 110. In an embodiment, the device interface board 50 further includes termination circuit module, amplifier circuit module, optional backup resource module, and self-test circuit module.

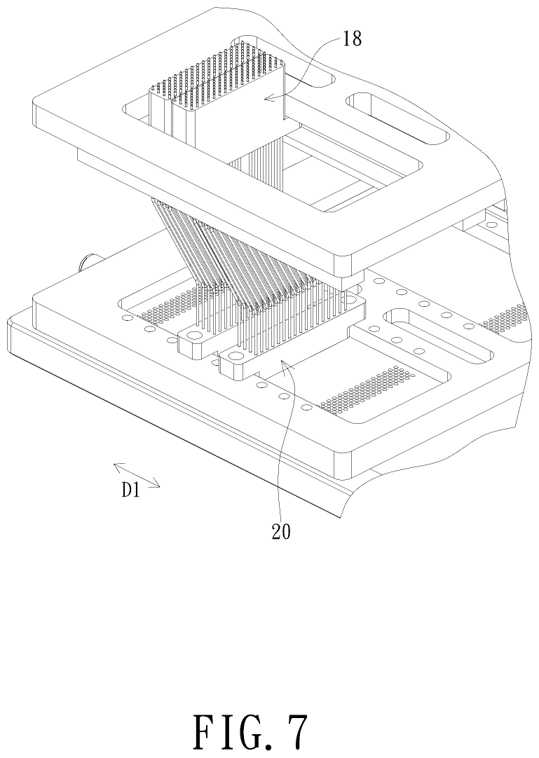

FIG. 7 is a schematic diagram of an application of a device interface according to an embodiment of the present invention. The fixing rib structures 36, the adjusting rib structures 38, and the second rail structures 44 are skipped for clarity. As shown in FIG. 7, the second probe device 20 is adapted to slide corresponding to the probe module 110 (as shown in FIG. 1) of the test head 100 along the direction D1. According to the configuration of the probe module 110, the second probe devices 20 can be arranged separately or adjoined to each other. As shown in FIG. 7, the plurality of second probe device 20 are arranged separately, but not limited thereto. The first probe devices 18 can be slid along the first direction D1 to be positioned adjacent to each other.

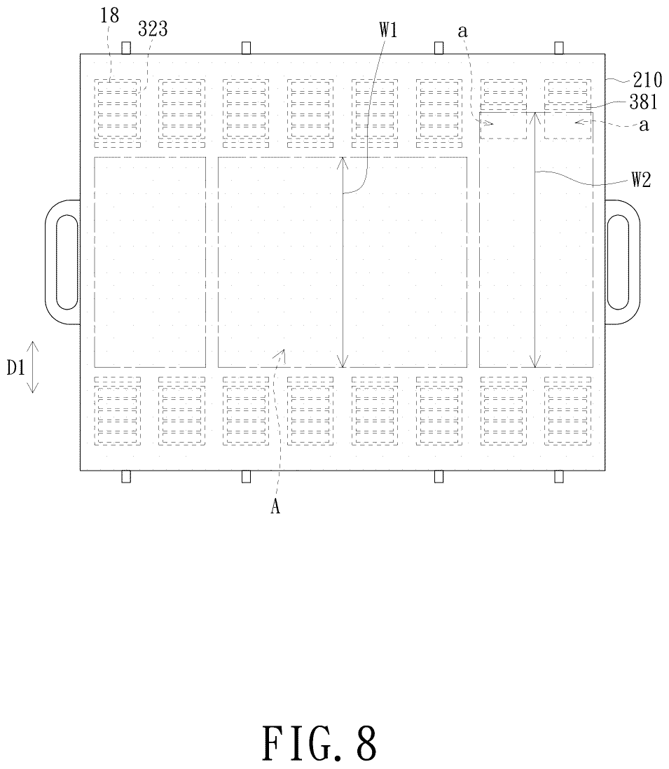

FIG. 8 is a schematic top view showing an application of a device interface and a performance board according to an embodiment of the present invention. The first probe devices 18 and the limiting part 381 are simplified for clarity. As shown in FIG. 8, the plurality of first probe devices 18 are positioned adjoined to one another within the first adjusting area 323. Therefore, the space occupied on the performance board 210 by the test resource area 211 (as shown in FIG. 2), which is used for electrical connection with the first probe device 18, can be appropriately reduced. In addition, in the two first adjusting areas 323 located at the upper right corner, due to the smaller number of first probe devices 18 (for example, only two sets of the first probe devices 18 in each of the first adjusting areas 323), and by sliding the limiting part 381 toward the edge of the performance board 210, as well as utilizing the top surface of the limiting part 381 to support the inner surface 213 of the performance board 210 adjacent to the edge, the space between the limiting part 381 and the central region of the inner surface 213 is released. This increases the usable area A for placing devices. As a result, a width of the usable area A in the first direction D1 can be expanded from the original width W1 to the width W2, thereby increasing the total area of the usable area A.

In the aforementioned embodiment, the first probe devices 18 are arranged adjoined to each other by sliding the first probe devices 18 and the limiting part 381, thereby increasing the usable area A. The invention is not limited thereto. In the device interface 10 according to another embodiment, the arrangement of the first probe devices can be adjusted according to the distribution of the test resource area 211 on the performance board 210. Thus, even when some unreasonable arrangements exist in varied standard test heads 100, such as too much empty space in the probe modules 110 or too large spacing between the modules 110, the first probe modules 18 can be rearranged to meet the requirement of the predetermined performance board 210, thereby increasing a flexibility for the compatibility between the performance board 210 and the test head 100 rather than being restricted by the distribution of probe modules 110 of the standard test heads 100. In other words, by utilizing the device interface 10 according to an embodiment of the present invention, the problem of the unreasonable arrangement of the probe modules 110 of the standard test head 100 existing in the conventional test devices can be solved. Also, the problem of insufficient layout area for the electronic device 214 (shown in FIG. 1) which is due to the large area occupied by the test resource area 211 on the performance board 210 can be effectively solved.

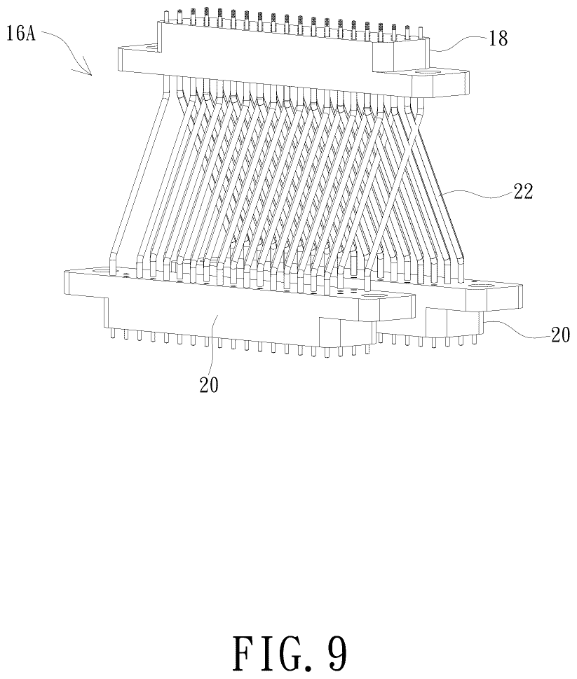

FIG. 9 is a schematic diagram of an interconnection structure according to a second embodiment of the present invention. In comparison with the interconnection structure 16 in the first embodiment as shown in FIG. 6, which is adapted for one-to-one connection with the probe devices, an interconnection structure 16A in the second embodiment is adapted for one-to-many or many-to-one connection with the probe devices. As shown in FIG. 9, in the interconnection structure 16A according to the second embodiment of the invention, a quantity of the first probe device 18 is one, and a quantity of the first probe device 18 is plural, such as two. The second probe devices 20 are electrically connected to the same first probe device 18 through the connecting component 22. As shown in FIG. 9, a distribution and density of the first pogo pins 182 of the first probe device 18 is obviously greater than a distribution and density of the second pogo pins 202 of the second probe device 20. It is understood that when the device interface 10 utilizes the interconnection structure 16A according to the second embodiment, there are two or more second probe devices 20 connected to the same first probe device 18. Under the same quantity of the second probe devices 20, the quantity of the first probe device 18 becomes less, thereby decreasing the space occupied by the first probe devices 18 which are disposed next to each other. Furthermore, the occupied area of the test resource area 211 can be shrunk in advance, leading to an increased usable area A for devices on the performance board 210 and a higher usage efficiency of the inner surface 213 of the performance board 210.

According to an embodiment not illustrated here, an interconnection structure, which can be different from or opposite to the interconnection structure 16A disclosed in the second embodiment of the invention, includes a plurality of first probe device 18 and a single second probe device 20. The two or more first probe devices 18 are electrically connected to the same second probe device 20 through a connecting component 22. Thus, it allows a high-density probe module 110 to be applied to a performance board 210 with low-density test resource areas 211, thereby improving the compatibility of the performance board 210.

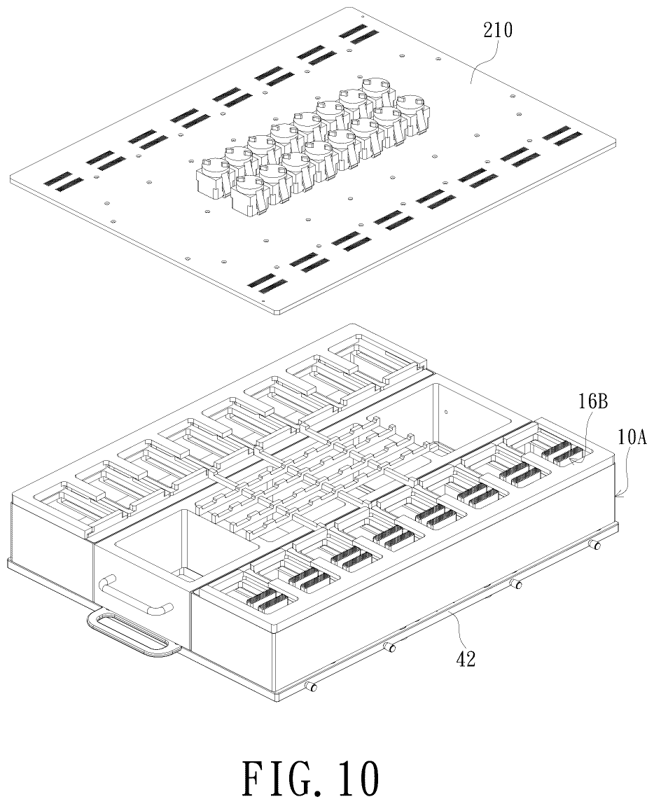

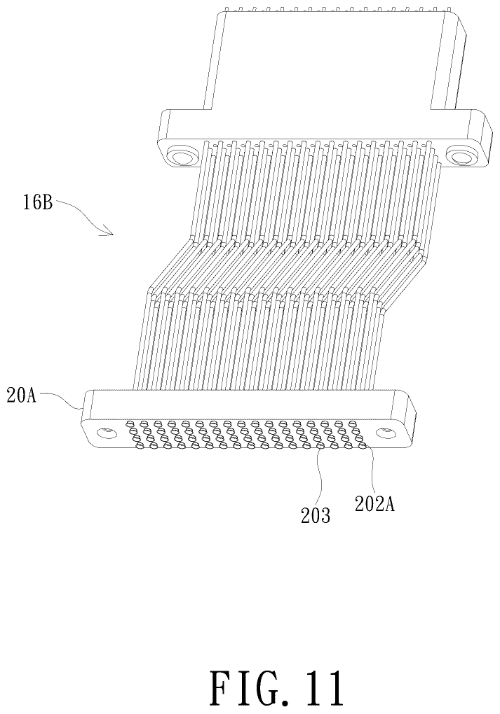

FIG. 10 is a schematic perspective view of a device interface and a performance board according to another embodiment of the present invention. FIG. 11 is a schematic diagram of an interconnection structure according to a third embodiment of the present invention. Unlike the device interface 10 shown in FIG. 2, a device interface 10A in FIG. 10 does not include the device interface board 50 and the docking frame 52 but include an interconnection structure 16B according to a third embodiment of the invention accordingly. As shown in FIG. 10, a second frame 42 of the device interface 10A is adapted to be assembled on the test head (illustrated in FIG. 1). Since the device interface 10A does not include a device interface board 50, in the interconnection structure 16B according to the third embodiment as shown in FIG. 11, each of the second pogo pins 202A of a second probe device 20A includes a receptacle 203 at one end toward the test head 100. The receptacle 203 is adapted to receive a test resource probe 111 of the probe module 110 (illustrated in FIG. 1) and to form an electrical connection therebetween.

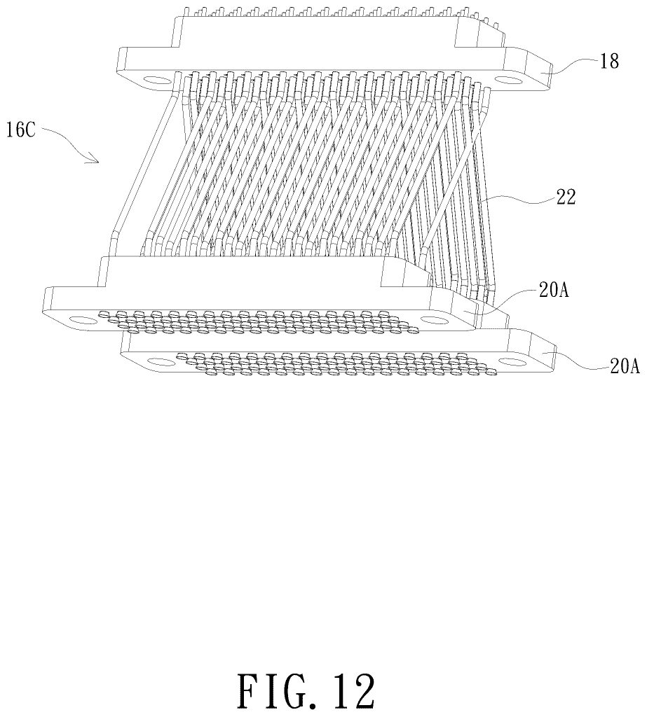

FIG. 12 is a schematic diagram of an interconnection structure according to a fourth embodiment of the present invention. In comparison with the interconnection structure 16B according to the third embodiment, which is adapted for one-to-one connection, an interconnection structure 16C according to the fourth embodiment is adapted for one-to-many or many-to-one connection. As shown in FIG. 12, the interconnection structure 16C according to the fourth embodiment includes a single first probe device 18 and two or more second probe devices 20A, which are electrically connected to the same first probe device 18 through a connecting component 22. In an embodiment not illustrated, unlike the fourth embodiment, an interconnection structure includes a plurality of first probe devices 18 and a single second probe device 20A. The plurality of first probe devices 18 are electrically connected to the same second probe device 20A through a connecting component 22.

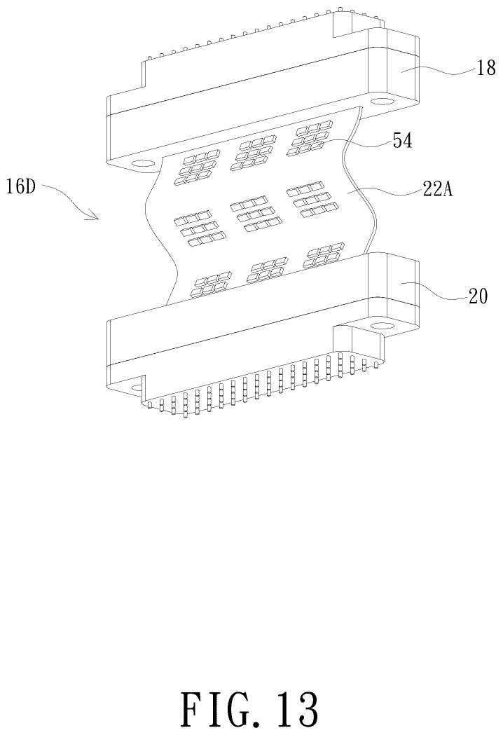

The connecting component 22 includes a cable or a flexure print circuit board (FPC). In the embodiment mentioned above, the connecting component 22 is illustrated as a cable (such as a flexure flat cable, FFC) but not limited thereto. FIG. 13 is a schematic diagram of an interconnection structure according to a fifth embodiment of the present invention. As shown in FIG. 13, an interconnection structure 16D according to a fifth embodiment includes a connecting component 22A which is a flexure print circuit board. Two ends of the connecting component 22A are electrically connected to a first probe device 18 and a second probe device 20. In an embodiment, the interconnection structure 16D further includes a signal quality enhancement module 54 which is disposed on and electrically connected to the flexure print circuit board (which is the connecting component 22A). The signal quality enhancement module 54 includes corresponding capacitor or resistor circuits disposed on another smaller flexure print circuit board or a printed circuit board assembly (PCBA). The signal quality enhancement module 54 is electrically connected to the interconnection structure 16D (the connecting component 22A) through a proper connecting manner, such as welding, thereby improving the signal quality transmitted between the first probe device 18 and the second probe device 20.

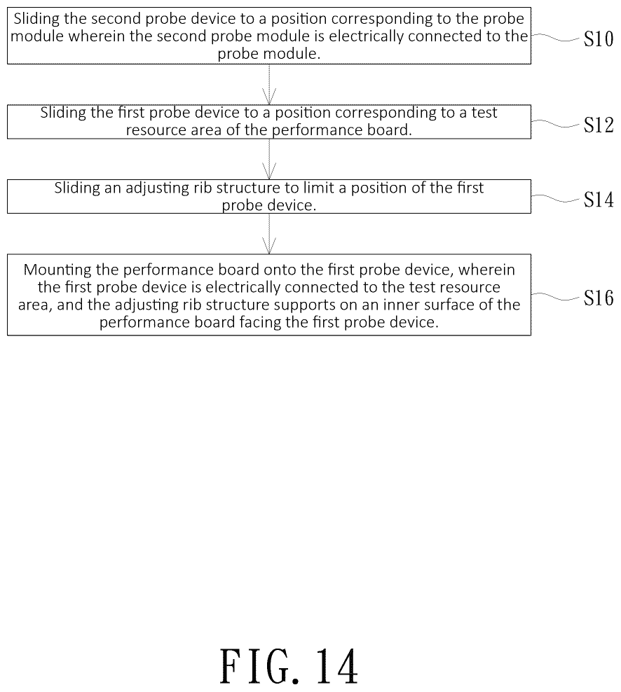

FIG. 14 is a schematic flow chart of a method of testing using the device interface according to an embodiment of the present invention. As shown in FIG. 14, Step S10 is first performed to slide the second probe device 20 to a position corresponding to the probe module 110 of the test head 100. The second probe device 20 is electrically connected to the probe module 110. Next, Step S12 is followed to slide the first probe device 18 a position corresponding to the test resource area 211 of the performance board 210 for being electrically connected to the test resource area 211 later. After that, Step S14 is performed to slide the adjusting rib structure 38 to limit the position of the first probe device 18. Finally, Step S16 is performed to mount the performance board 210 on the first probe device 18. The first probe device 18 is electrically connected to the test resource area 211 and the adjusting rib structure 38 supports on the inner surface 213 of the performance board 210 facing the first probe device 18.

In an embodiment, the movement of the first probe device 18, the second probe device 20, and the adjusting rib structure 38 can be automatically controlled through programing.

As mentioned above, the device interface and the method of testing utilizing the device interface according to the present invention include at least one advantage as below.

(1) With the slide and position adjustment of the first probe device and the second probe device, the performance board with the same configuration (the same distribution of the test resource areas) can be applied to different test heads with different configurations, thereby increasing the flexibility of the test heads and the performance board.

(2) It solves the problem in traditional test devices where the standard probe modules of the test head have unreasonable configurations, thereby causing the test resource area on the performance board to occupy a large space and leading to insufficient area for electronic device placement.

(3) The first probe devices can be slid along the first direction and thereby be arranged adjoined to each other. As a result, the required area on the performance board for electrically connecting to the first probe devices can be properly decreased. By positioning the adjusting rib structures to support the inner surface of the performance board adjacent to the edge, the space between the adjusting rib structure and the central region of the inner surface can be released, thereby increasing the usable area for the device placement.

(4) By utilizing the design of the interconnection structure where two or more second probe devices are electrically connected to the same first probe device through the connecting component, the usable area on the performance board can be further increased, thereby improving the usage rate of the inner surface of performance board.

(5) By utilizing the design of the interconnection structure where two or more first probe devices are electrically connected to the same second probe device through the connecting component, the probe module with a high probe density can be applied to the performance board with a low density of test resource areas, thereby improving the compatibility of the performance board.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A device interface disposed between a test head and a device under test, the test head comprising a plurality of probe modules, the device under test comprising a performance board, the device interface comprising:
a first mounting structure;
a second mounting structure; and
at least one interconnection structure, each of the at least one interconnection structure comprising at least one first probe device, at least one second probe device, and a connecting component which is electrically connected to the at least one first probe device and the at least one second probe device;
wherein the at least one first probe device is slidably mounted on the first mounting structure and adapted to be electrically connected to the performance board, and the at least one second probe device is slidably mounted on the second mounting structure and adapted to be electrically connected to the probe modules.

2. The device interface according to claim 1, wherein in each of the at least one interconnecting component, a quantity of the at least one first probe device is one, a quantity of the at least one second probe device is one, and the connecting component is electrically connected to the first probe device and the second probe device.

3. The device interface according to claim 1, wherein in each of the at least one interconnecting component, a quantity of the at least one first probe device is one, a quantity of the at least one second probe device is plural, and the plurality of the second probe devices are electrically connected to the same first probe device through the connecting component.

4. The device interface according to claim 1, wherein in each of the at least one interconnecting component, a quantity of the at least one first probe device is plural, a quantity of the at least one second probe device is one, and the plurality of the first probe devices are electrically connected to the same second probe device through the connecting component.

5. The device interface according to claim 1, wherein the connecting component is a cable.

6. The device interface according to claim 1, wherein the connecting component is a flexure print circuit board.

7. The device interface according to claim 6, wherein the interconnection structure further comprises a signal quality enhancement module which is disposed on and electrically connected to the flexure print circuit board.

8. The device interface according to claim 1 further comprising a base, wherein the base comprises a first loading side and a second loading side opposite the first loading side, the first loading side comprises a first probe configuration area, the second loading side comprises a second probe configuration area, the first mounting structure is disposed in the first probe configuration area, the second mounting structure is disposed in the second probe configuration area, and the connecting component is disposed within the base.

9. The device interface according to claim 8, wherein the first probe configuration area comprises two divided and opposite rectangular areas, or two divided and opposite semi-ring areas or a frame-shaped area.

10. The device interface according to claim 8, wherein a size of the first probe configuration area is less than or equal to that of the second probe configuration area.

11. The device interface according to claim 8, wherein a quantity of the at least one interconnection structure is plural, the device interface further comprises an adjusting structure disposed in the base to separate the connecting components of the interconnection structures.

12. The device interface according to claim 8, wherein the first mounting structure comprises a first frame and a plurality of first rail structures,
the first frame is disposed in the first probe configuration area in the first loading side of the base, the first frame comprises two divided first side frames and a plurality of first support members, the first support members are disposed at intervals and connected to both of the first side frames for forming a plurality of first adjusting areas, and
the first rail structures are disposed on the first support member and on two opposite sides of each of the first adjusting areas.

13. The device interface according to claim 12, wherein each of the at least one first probe device comprises a first probe socket and a plurality of first pogo pins,
the first probe socket comprises two opposite first guiding bumps adapted for being movably assembled on the first rail structure to enable the first probe socket to slide in the first adjusting area along a first direction, a portion of the first probe socket extends between the first frame and the performance board,
the first pogo pins are assembled on the first probe socket and protrudes the first probe socket, and one end of the first pogo pins is connected to the connecting component while the other end of the first pogo pins is adapted to be electrically connected to the performance board.

14. The device interface according to claim 12, wherein the first mounting structure further comprises a fixing rib structure and a plurality of adjusting rib structures,
the fixing rib structure comprises a fixing part and a plurality of suspended ribs, the fixing part is disposed on one of the two first side frames, the suspended ribs are arranged at intervals on the fixing part, the suspended ribs are arranged corresponding to the first support members, the suspended ribs and the corresponding first support members form a slidable space,
the adjusting rib structures are arranged corresponding to the first adjusting areas, each of the adjusting rib structures comprises a limiting part and two sliding ribs, the two sliding ribs are slidably arranged on the first support members on the two sides of the first adjusting area and adapted to slide in the slidable space for moving the limiting part close to or away from the fixing part of the fixing rib structures, and the limiting part is adapted to support an inner surface of the performance board facing the first probe device.

15. The device interface according to the claim 12, wherein the second mounting structure comprises a second frame and a plurality of second rail structures,
the second frame is disposed in the second probe configuration area on the second loading side of the base, the second frame comprises two divided second side frames and a plurality of second support members, the second support members are disposed at intervals and connected to the two second side frames for forming a plurality of second adjusting areas, the second adjusting areas are corresponding to the first adjusting areas respectively,
the second rail structures are disposed on the second support members and on two opposite sides of each of the second adjusting areas, and the second rail structures correspond to the first rail structures respectively.

16. The device interface according to claim 15, wherein each of the at least one second probe device comprises a second probe socket and a plurality of second pogo pins,
two opposite sides of the second probe socket are adapted for being movably assembled on the second rail structure to make the second probe socket slide in the second adjusting area along a first direction,
the second pogo pins are assembled on the second probe socket and protrudes the second probe socket, and one end of the second pogo pins is connected to the connecting component while the other end of the second pogo pins is adapted to be electrically connected to the probe module.

17. The device interface according to claim 16 further comprises a device interface board and a docking frame, wherein the docking frame is adapted to be assembled onto the test head, the device interface board is disposed between the second frame and the docking frame, and the second pogo pins are electrically connected to the probe module through a transition structure formed by the device interface board.

18. The device interface according to claim 16, wherein the second pogo pin comprises a receptacle at one end toward the test head adapted to receive a test resource probe of the probe module and form an electrical connection therebetween.

19. A method of testing utilizing the device interface according to claim 1, wherein the method comprises:
sliding the second probe device to a position corresponding to the probe module of the test head, wherein the second probe device is electrically connected to the probe module;
sliding the first probe device to a position corresponding to a test resource area of the performance board;
sliding an adjusting rib structure to limit a position of the first probe device; and
mounting the performance board onto the first probe device, wherein the first probe device is electrically connected to the test resource area, and the adjusting rib structure supports on an inner surface of the performance board facing the first probe device.

20. A method according to claim 19, wherein the movement of the first probe device, the second probe device, and the adjusting rib structure can be automatically controlled through programing.
